(19) United States
(12) Patent Application Publication
(10) Pub. No.: US 2024/0088259 A1
(43) Pub. Date: Mar. 14, 2024

(54) VERTICAL ALUMINUM GALLIUM NITRIDE DEVICES ON CRYSTALLINE METALLIC SUBSTRATES

(71) Applicants: Alliance for Sustainable Energy, LLC, Golden, CO (US); University of South Carolina, Columbia, SC (US)

(72) Inventors: Marshall Brooks TELLEKAMP, Jr., Denver, CO (US); MVS CHANDRASHEKHAR, Columbia, SC (US)

(21) Appl. No.: 18/464,761

(22) Filed: Sep. 11, 2023

Related U.S. Application Data
(60) Provisional application No. 63/375,089, filed on Sep. 9, 2022.

(51) Int. Cl. H01L 29/66; H01L 21/02; H01L 29/04

(52) U.S. Cl. CPC H01L 29/66431; H01L 21/02425; H01L 21/0254; H01L 29/045

(57) ABSTRACT

Described herein are systems and methods for the facile growth of aluminum gallium nitride semiconductor devices by utilizing specific lattice matched substrates. These substrates include metal borides, for example, ScB₂, HfB₂ and ZrB₂ and metal carbides and metal nitrides. These substrates may allow for the cost effective manufacturing of ultra-wide bandgap semiconductor devices.

### CROSS-REFERENCE TO RELATED APPLICATIONS

This application claims priority from U.S. Provisional Patent Application No. 63/375,089 filed on Sep. 9, 2022, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### SUMMARY

Described herein are systems and methods for the facile growth of aluminum gallium nitride semiconductor devices by utilizing specific lattice matched substrates. These substrates include metal borides, for example, ScB₂, HfB₂ and ZrB₂ and metal carbides and metal nitrides. These substrates may allow for the cost effective manufacturing of ultra-wide bandgap semiconductor devices. Advantageously, the described substrates may be removeable, by either lift off or etching or may be conductive and useful remaining in an optoelectronic device stack.

In an aspect, provided is a device comprising: a) a semiconducting material comprising AlₓGa₁₋ₓN where 0<x<1; and b) a substrate having the formula MB₂, wherein B is Boron and M is a metal comprising at least one of the group of Zr, Hf, Sc, Nb, Ta, Ti, V, Cr, Mn, Y, Mo, Mg, Al and U.

In an aspect, provided is a device comprising: a) a semiconducting material comprising AlₓGa₁₋ₓN where 0<x<1; and b) a substrate having the formula M₂N or M₂C, wherein C is carbon, N is nitrogen and M is a metal comprising at least one of the group of Zr, Hf, Sc, Nb, Ta, Ti, V, Cr, Mn, Y, Mo, Mg, Al and U.

In an aspect, provided is a device comprising: a) a semiconducting material comprising AlₓX₁₋ₓN where 0<x<1; wherein X comprises at least one of the group of Ga, In, Sc, Gd, or a combination thereof; and b) a substrate having the formula MB₂, wherein B is Boron and M is a metal comprising at least one of the group of Zr, Hf, Sc, Nb, Ta, Ti, V, Cr, Mn, Y, Mo, Mg, Al and U.

In an aspect, provided is a device comprising: a) a semiconducting material comprising AlₓX₁₋ₓN where 0<x<1; wherein X comprises at least one of the group of Ga, In, Sc, Gd, or a combination thereof and b) a substrate having the formula M₂N or M₂C, wherein C is carbon, N is nitrogen and M is a metal comprising at least one of the group of Zr, Hf, Sc, Nb, Ta, Ti, V, Cr, Mn, Y, Mo, Mg, Al and U.

In an aspect, provided is an epitaxial substrate having the formula MB₂, wherein B is Boron and M is a metal selected from the group of Zr, Hf, Sc, Nb, Ta, Ti, V, Cr, Mn, Y, Mo, Mg, Al and U; wherein the substrate is lattice matched to AlₓGa₁₋ₓN for 0<x<1; and wherein the substrate is a single orientation crystal.

In an aspect provided is a method comprising: providing a single orientation crystal epitaxial substrate having the formula MB₂, wherein B is Boron and M is a metal selected from the group of Zr, Hf, Sc, Nb, Ta, Ti, V, Cr, Mn, Y, Mo, Mg, Al and U; growing a AlₓGa₁₋ₓN semiconductor layer on the substrate; wherein the substrate is lattice matched to AlₓGa₁₋ₓN.

In an aspect, provided is a method comprising: providing a epitaxial substrate; depositing a carbonitride layer comprising a transition metal cation and N, C or a combination thereof on a surface of the high-temperature substrate thereby generating an epitaxial substrate; growing a AlₓGa₁₋ₓN semiconductor layer on the epitaxial substrate; removing the epitaxial substrate from the AlₓGa₁₋ₓN semiconductor layer.

Examples of metal borides (MB₂) include ScB₂, HfB₂ and ZrB₂. The substrate may be lattice matched along an in-plane direction, for example the a-direction, to the substrate. The substrate may have a lattice mismatch less than equal to 1% for AlGaN, including high aluminum content AlGaN, for example, Al_{0.5}Ga_{0.5}N. The semiconductor may have a high content of Al, including a mole fraction greater than 0.5, 0.6 or 0.7, which is advantageous in ultra-wide bandgap semiconductor application, for example, by increasing bandgap or transparency.

The substrate may have a hexagonal (001) or (111) crystal structure. For metal borides, the crystal structure is hexagonal along the (001) or (0001) face. For metal carbides and metal nitrides (also referred to a rock salts), the hexagonal structure is present when viewed along the (111) plane.

The substrates may exhibit semimetallic or metallic electron transfer. This may be described as having an increase in resistivity with increasing temperature or by exhibiting thermal generation of carriers. Metallic electron transfer may also be described as having a resistance less than or equal to 0.0001 or 0.001 Ωcm.

The described devices may be useful in both bulk and thin film semiconductor generation. For example the semiconducting material may have a vertical thickness greater than or equal to 0.5 μm, 1.0 μm, or optionally, 1.5 μm. The semiconducting layer may have a threading dislocation density in an epilayer less than or equal to 0.5×10⁷ cm⁻2, 1×10⁷ cm⁻², or optionally 2×10⁷ cm⁻².

The device may be or comprise an ultra-wide bandgap semiconductor, as described herein. The device may also have a vertical or pseudo-vertical orientation.

The substrate may also be removable, for example, via liftoff or acid etching. The substrate may be acid soluble, including in HF, HNO₃ or a combination thereof. Other useful acids or etchants include sulfuric or sulfamic acids, NH₄F, molten KOH or NaOH, HClO₄, H₂O₂, KNO₃, K₂SO₄, Na₂O₂, and aqua regia. In the case of metal borides, fused oxides and salts such as lead oxide and Na₂O₂ may also be used.

Examples of carbonitride substrates (or metal carbide and metal nitride substrates) include TaC, TaN, NbN, NbC, ZrN, ZrC, ScC, ScN, HfN, HfC. Examples of useful transition metals include: Ta, Nb, Sc, Hf, Zr or combinations thereof. These substrates may have a ground state of rock salt. These substrates may also be temperature resistant, e.g., non-melting at deposition temperatures necessary for AlGaN.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1A illustrates uses of ultra-wide bandgap semiconductors in extreme applications.

FIG. 1B provides a comparison of various figures of merit (FOM) normalized to Si, as a function of bandgap. Only 2 UWBG materials have a chance to have both p/n doping in realistic device structures.

FIG. 2A provides an example of a n⁺/p⁻ junction diode for demonstration of conductivity modulation and measurement of E_{C} in AlGaN.

FIG. 2B provides an example of a Schottky diode for measurement of E_{C}, and to demonstrate lowest R_{on,sp}, as electrons have higher p. Both devices in FIGS. 2A-2B have field plates for electric field management at device edge.

FIG. 3 illustrates a 5 mm×55 mm long single crystal CB₄ grown by laser FZ method with the X-ray Laue pattern from the hexagonal (001) orientation showing clear 3-fold symmetry over >5 cm, from which over 50 wafers can be cut/polished.

FIG. 4A shows the UWBG III-N alloy space as a function of band gap and lattice constant, along with prospective carbide (111 effective) and diboride (0001) lattice constants. Of interest is the power electronics region of interest (shaded) where there are no currently available substrates (shaded). NbC (111) and ScB2 (0001) lattice structures are shown to scale with Al0.5Ga0.5N.

FIG. 4B provides example Schottky barrier diodes (SBD) and PiN diodes capable of high-current handling and >1 kV blocking with a 2 μm thick drift layer.

FIG. 4C provides a comparison of thermal and electrical substrate factors, showing the superiority of carbides and borides with respect to current state-of-the-art substrates.

FIG. 5 provides an example schematic of three dimensional lift off while comparing temperature and power. Layer (1) is a high temperature epitaxial substrate, Layer (2) is MB₂ or a transition metal carbonitride, Layer (3) is AlₓGa₁₋ₓN (where 0<x<1) and Layer (4) is a handle.

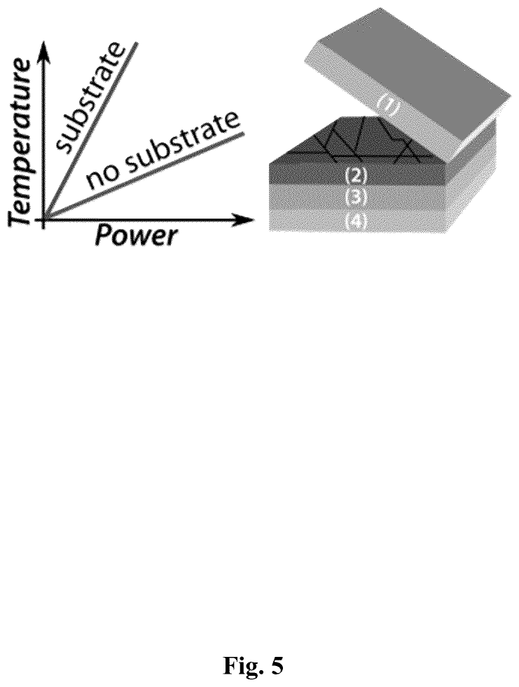

FIG. 6 provides an example schematic of a device as described herein. Layer (1) is MB₂ and Layer (2) is AlₓGa₁₋ₓN (where 0<x<1).

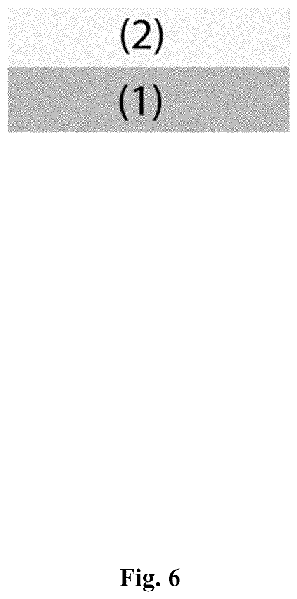

FIG. 7 illustrates effective lattice spacing for a transition metal carbonitride, AlₓGa₁₋ₓN, and MB₂, respectively.

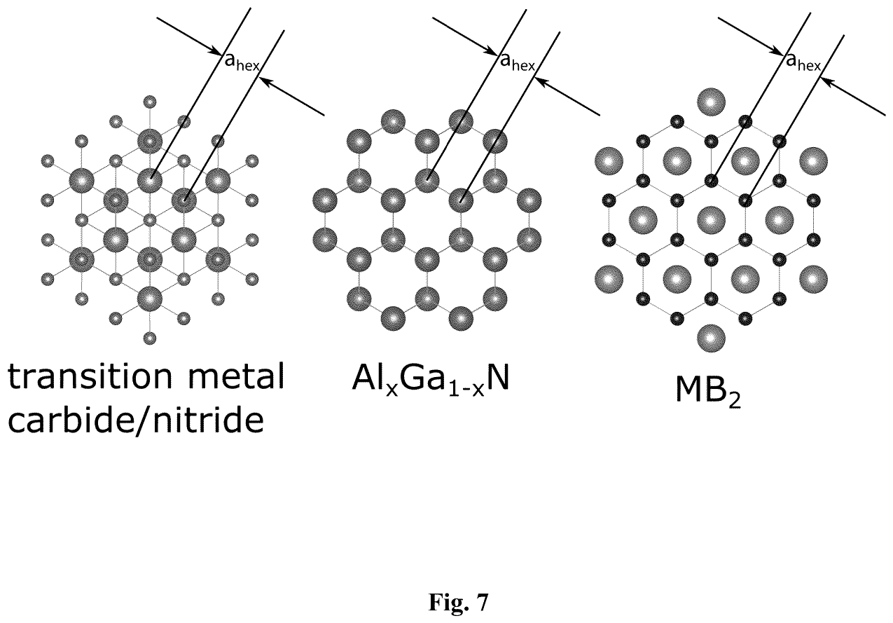

FIG. 8 provides example devices as described herein, including an all AlGaN vertical p-i-n diode (left) and an all AlGaN vertical Schottky barrier diode.

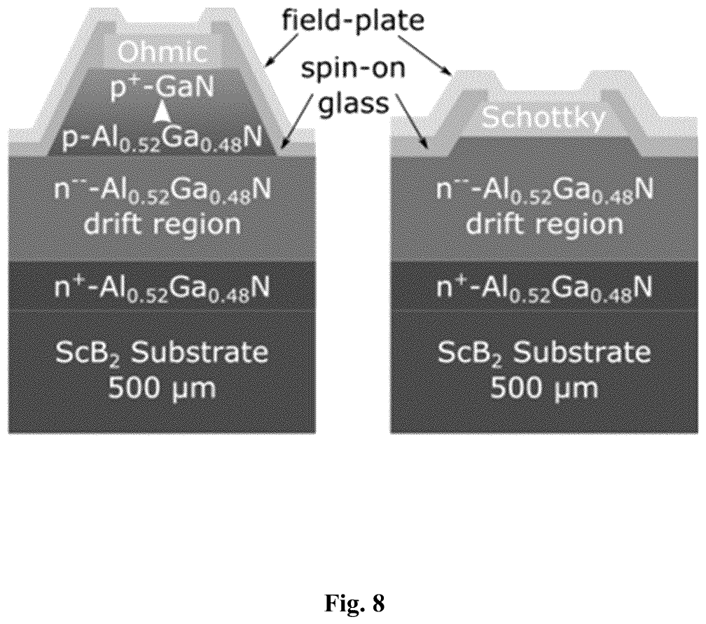

FIG. 9 illustrates laser lift off of an example device as shown in FIG. 5 from left to right, where Layer (1) is a high temperature epitaxial substrate, Layer (2) is MB₂ or a transition metal carbonitride, Layer (3) is AlₓGa₁₋ₓN (where 0<x<1) and Layer (4) is a handle.

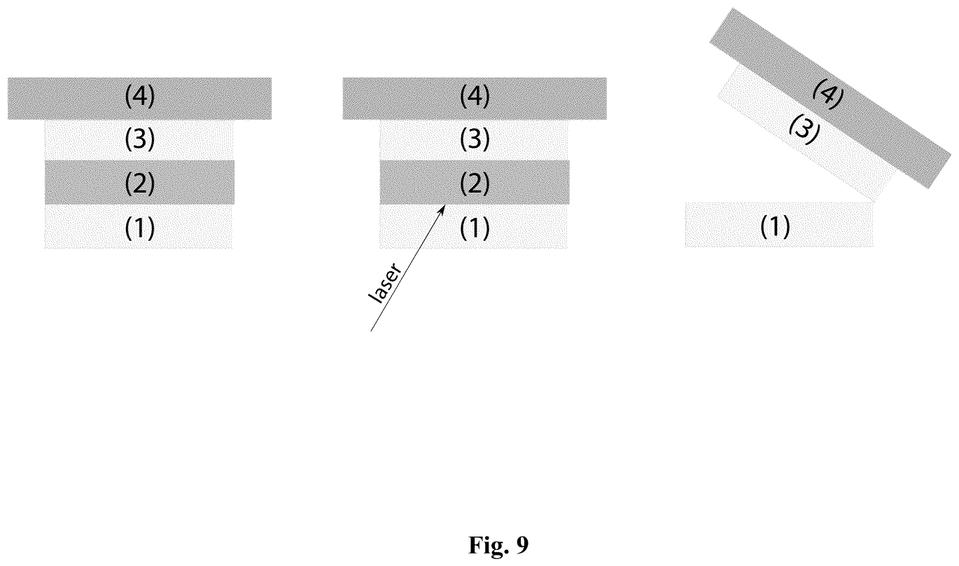

FIG. 10 illustrates wet etchant lift off of an example device as shown in FIG. 5 from left to right, where Layer (1) is a high temperature epitaxial substrate, Layer (2) is MB₂ or a transition metal carbonitride, Layer (3) is AlₓGa₁₋ₓN (where 0<x<1) and Layer (4) is a handle.

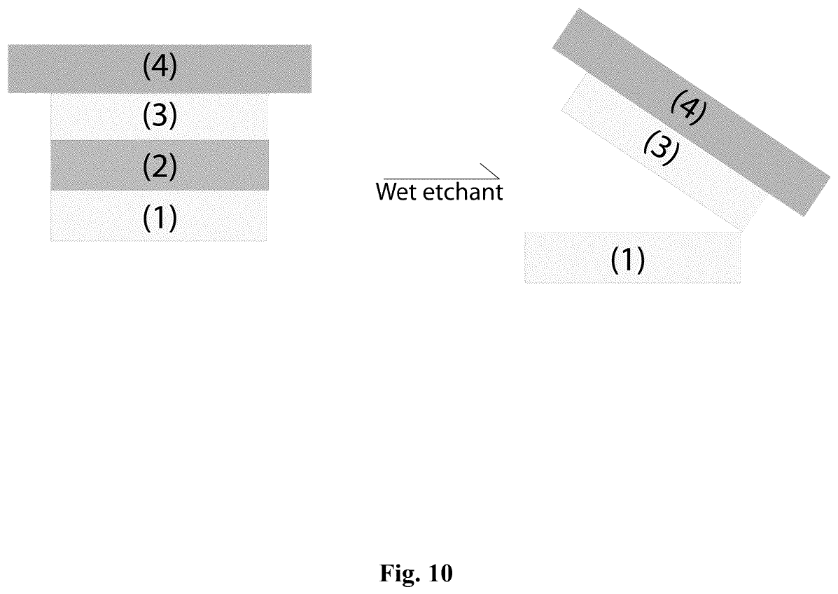

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The provided discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

### Example 1—Floating Zone Grown Metal Diboride (MB₂) Single Crystals, as Electrically, Thermally Conductive, and Lattice Matched Substrates for UWBG III-Nitrides in Extreme Vertical Power Devices

Described herein are systems and methods to grow electrically, thermally conductive, metal diboride (MB₂) single crystals as refractory lattice-matched substrates for ultra-wide bandgap (UWBG) AlₓGa₁₋ₓN (x>0.5) ternaries by a floating zone (FZ) method. These are cut into wafers, polished and prepared for epitaxial growth of pseudomorphic 1 kV diodes by MOCVD, requiring ˜2 μm thick layers doped at ˜2-3×10¹⁷ cm⁻³. Both n-Schottky diodes and n⁺/p⁻ junction diodes will then be fabricated and characterized. Due to the superior lattice matching of MB₂ to x˜0.5-0.7 AlₓGa₁₋ₓN, particularly ScB₂ and HfB₂, the threading dislocation density (TDD) in the epilayers is much lower than on any other substrate commercially available today. The superior lattice match of MB₂ substrates also enables much thicker epilayers to be grown beyond the ˜1 μm currently possible on AlN templates/substrates, allowing scaling to well beyond 5 kV for >5 μm thick films. Finally, the low TDD and enables the experimental measurement of the intrinsic critical breakdown field (E_{C}) of AlₓGa₁₋ₓN, currently limited by TDD>>10⁷ cm⁻². This may provide a 10× increase in current densities over state-of-the-art wide bandgap devices, such as GaN/SiC, leading to corresponding cost and switching speed advantages. This lattice matched substrate platform also enables low TDD applications in DUV LED's, as well as radiation detectors, which also require thick absorbing layers.

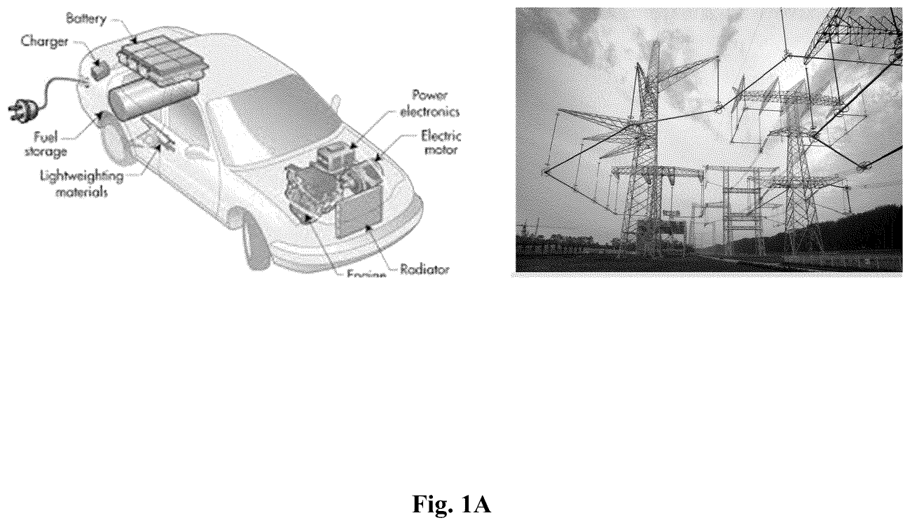

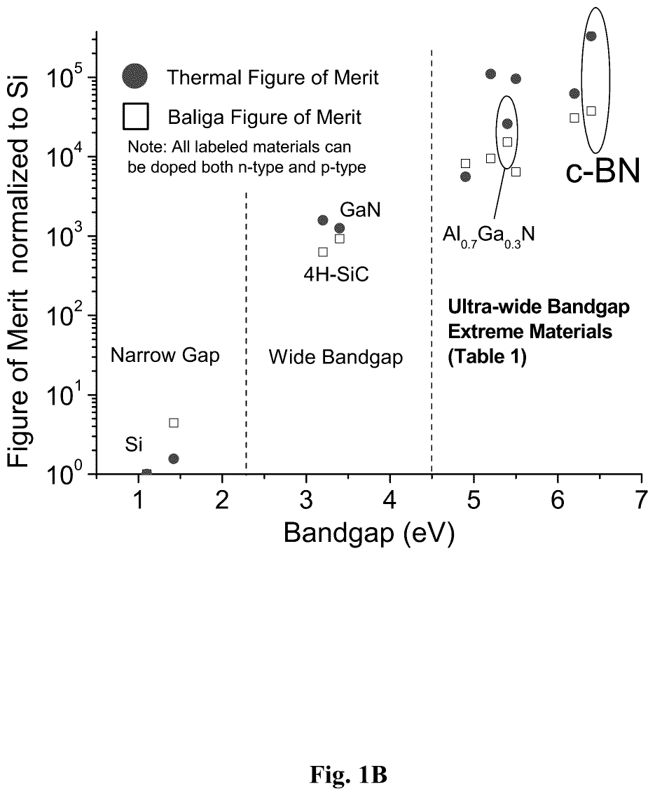

UWBG semiconductors AlGaN, Ga₂O₃, diamond and others have emerged as promising material technologies to succeed Si, SiC, and GaN power semiconductors, the current state-of-the-art. Their UWBG leads to large critical breakdown electric field (E_{C}), enabling larger voltages to be withstood in a smaller footprint, reducing on-resistance/capacitances, and thereby conduction/switching losses. This also enables higher frequency operation to be achieved, allowing system reduction through minimization of passive elements such as capacitors and inductors. Furthermore, their UWBG also provides for high temperature operation, which eliminates the need for active cooling, currently the limiting factor in high current applications such as hybrid electric vehicles. This is expressed in the Baliga figure of merit (BFOM), and the thermal figure of merit (TFOM): TFOM=K×BFOM=K×∈μE_{C}³, where ε is the dielectric constant, μ is the carrier mobility, while K is the thermal conductivity (FIG. 1B). The III-Nitrides have clear advantages over other semiconductors, as only AlGaN and cubic BN (c-BN) can be doped both n-type and p-type. c-BN is very difficult to grow, requiring complex non-equilibrium techniques. This leaves AlGaN as the compelling next-generation UWBG semiconductor, although substrates are a problem, either with poor lattice match (Si), poor thermal conductivity (sapphire), or poor electrical conductivity (AlN). Poor lattice match degrades material quality and limits the thickest layers that can be produced, which in turn limits the highest achievable voltages, and overall diode performance.

Metal diborides (MB₂) are high temperature hexagonal ceramics that are more conductive than semiconductor substrates by >100×, with resistivities in the 10⁻⁵ Ωcm range. They have excellent thermal conductivity, and lattice constants spanning from AlN, GaN, to InGaN (Table 1). This makes MB₂ attractive for lattice-matched substrates to AlₓGa₁₋ₓN ternary compounds, which currently do not have a matched substrate. As opposed to GaN, AlN, and SiC, which sublime/decompose at ambient pressures, MB₂ materials are well-behaved melters. With some MB₂ materials demonstrating congruent melting (i.e. composition of melt is identical to the solid), they are ideal for FZ growth [10]. FZ growth is also used in Si-power electronics, the industry workhorse, enabling easier wafer-scaling compared to GaN/SiC substrates that require specialized growth techniques.

TABLE 1
Room temperature values showing superior performance and lattice matching
of MB2 substrates to AlGaN epilayers. The thermal matching has not
been measured for many MB2 except ZrB2, which shows exceptional thermal
matching. ScB2 and HfB2 should show even better performance.

| | a | ρ | K | Melting point | Lattice matched | CTE |
|---|---|---|---|---|---|---|
| | (Å) | (Ω-cm) | (W/mK) | (° C.) | III-N | (ppm/K) |
| ScB₂ | 3.148 | 7-15 × 10⁻⁶ | unknown | 2250 | Al_{0.55}Ga_{0.45}N | ~7 |
| | | | (TBM) | (congruent) | (<0.1%) | |
| HfB₂ | 3.139 | ~10⁻⁵ | 104 | 3380 | Al_{0.65}Ga_{0.35}N | ~6 |
| | | | | (congruent) | (<0.05%) | |
| ZrB₂ | 3.170 | ~5 × 10⁻⁶ | ~100 | 3245 | GaN (<2%) | ~5.9 |
| | | | [13, 14] | (congruent) | | |
| GaN | 3.189 | 10⁻³-10⁻² | ~100 | sublimes | GaN | ~5.6 |
| AlN | 3.11 | >10⁺⁶ | ~300 | sublimes | AlN | ~4 |
| | | (insulating) | | | | |

Due to the superior lattice match of AlₓGa₁₋ₓN with ScB₂/HfB₂ compared to either AlN or GaN, thicker active device layers can be grown (compared to the ˜1 μm limit currently seen with AlN substrates/templates), enabling higher voltage blocking. In thick epitaxial layers, lattice mismatch strain is initially relieved through threading dislocations (TD's), and eventually through cracking. TD's degrade off-state voltage blocking, and the best blocking is seen in lattice matched diodes, such as GaN/GaN >3 kV compared to commercial <1 kV GaN/Silicon.

This has been previously validated, as it has been demonstrated heteroepitaxy of GaN on lattice matched FZ-grown ZrB₂, and also showed the thermal matching of this III-N/MB₂ system. Interestingly, this also favors the growth of N-polar III-N, which is the ideal polarity for polarization doping by electrons for making ohmic contacts to n-type AlGaN. However, during that time, most vertical GaN technology was for LED's, where the influence of TD's was not as critical.

For the BFOM/TFOM performance predicted in FIG. 1B for AlGaN to be achieved, the voltage drop across the substrate must be eliminated. For GaN/SiC substrates, even assuming that AlGaN can be grown despite the lattice mismatch, this parasitic substrate resistance dominates, leading to additional thermal load that must be handled. This substrate resistance also limits the switching speed for pulse-width modulation (PWM) due to RC effects. Using ScB₂, this is eliminated completely (Table 2), so that the dominant series resistance is from the diode itself. With MB₂ substrates, the overall current level handled by the diode increases by 5-10× over even high performance WBG substrates, leading to a 5-10× reduction in $/Ampere, as well as 5-10× faster switching speeds for PWM. The scaling offered by the silicon-compatible FZ method, enables further cost reductions as the technique matures.

TABLE 2
Estimated on-state resistances of Al0.6Ga0.4N diode, 2 μm thick,
doped at 2-3 × 1017, μ = 200 cm2/Vs

| | | |
|---|---|---|
| Substrate (400 μm thickness) NB: | | |
| Resistances add in series | ScB₂ | GaN/SiC |

| | |
|---|---|
| R_{on, sp, diode} (mΩ-cm²) | 3 × 10⁻² |

| | | |
|---|---|---|
| R_{sp, substrate} (mΩ-cm²) | 3-4 × 10⁻⁴ | 4 × 10⁻¹ |

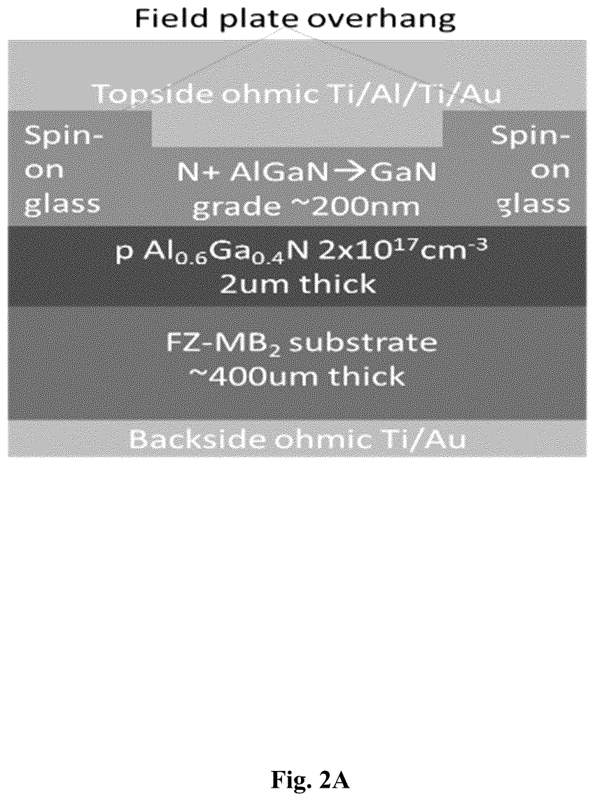

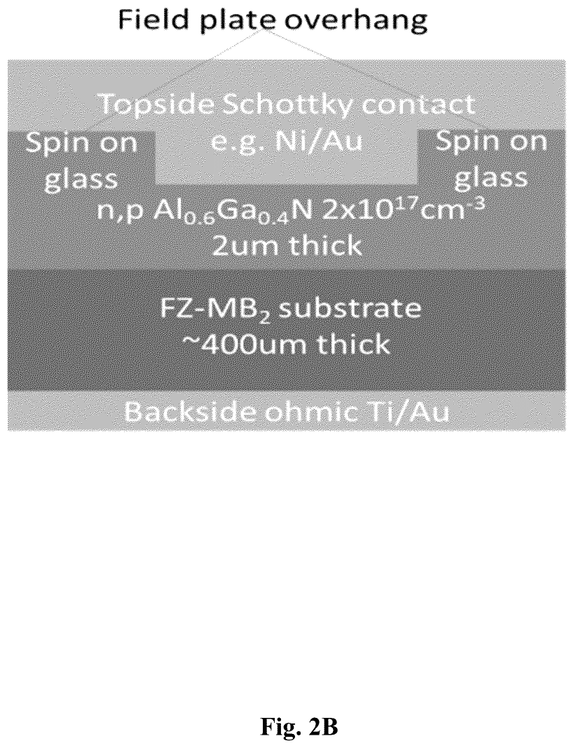

For the full promise of UWBG devices to be realized, vertical geometry devices i.e. with conduction through the bulk substrates must be used. Vertical devices enable high current handling/voltage blocking to be achieved in a smaller footprint, with the thermal management simplicity of the large area backside sink. Both n-type Schottky diodes, as well as n⁺/p⁻ junction diodes demonstrate the BFOM/TFOM advantages of Al_{0.6}Ga_{0.4}N as discussed herein (FIGS. 1A-1B). The described devices (FIGS. 2A-2B) are relatively easy to fabricate and enable the E_{C} for AlGaN to be measured. We describe ˜1 kV diodes, requiring ˜2 μm thick layers doped at ˜2-3×10¹⁷ cm⁻³, which translates to an estimated peak field ˜10 MV/cm for AlGaN. We anticipate conductivity modulation in the junction diode, as the diffusion length for electrons at μ=200 cm²/Vs and recombination time of ˜1 ns for direct gap materials is ˜1 μm, comparable to the length of the diode.

### Results

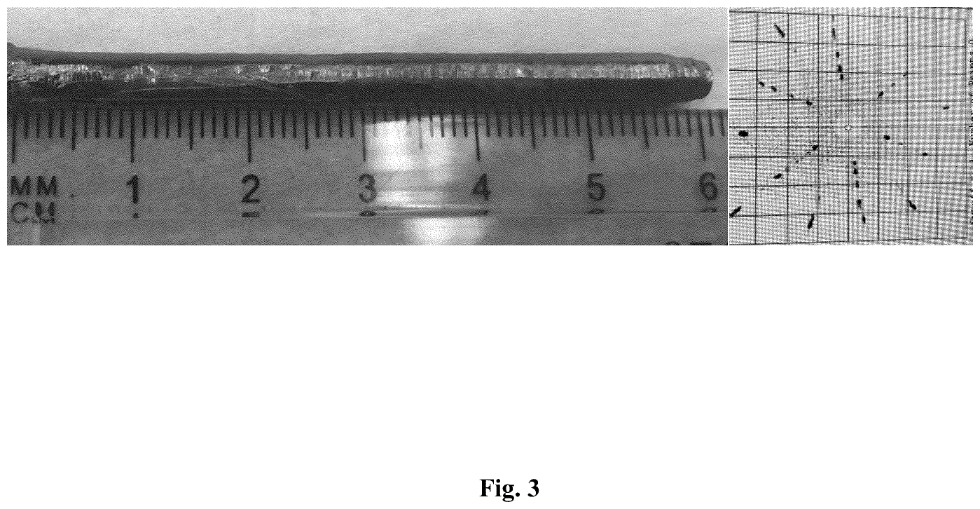

Boride growth using FZ: We have developed FZ growth of borides, a challenging material system owing to large oxygen/H₂O impurities/adsorbates inevitably present in boron based ceramics. This causes problems such as excess boron removal during FZ growth, leading to issues with stoichiometry control during growth. We have developed a zone-refining scheme, similar to that developed for Si, to eliminate this, leading to O-free boules of CB₄, another high temperature (MP˜2400° C., similar to ScB₂) conductive boride ceramic. FIG. 3 illustrates the first CB₄ single crystals grown in the US and shows the viability of our approach. Recent breakthroughs including both 2 terminal devices such as LED's, detectors and 3 terminal devices such as HEMT's that operate at elevated temperatures have been shown in the art.

### Example 2—Novel Metallic Ceramic Substrates to Enable Disruptive Performance Advances for Ultra-Wide Bandgap Power Electronics

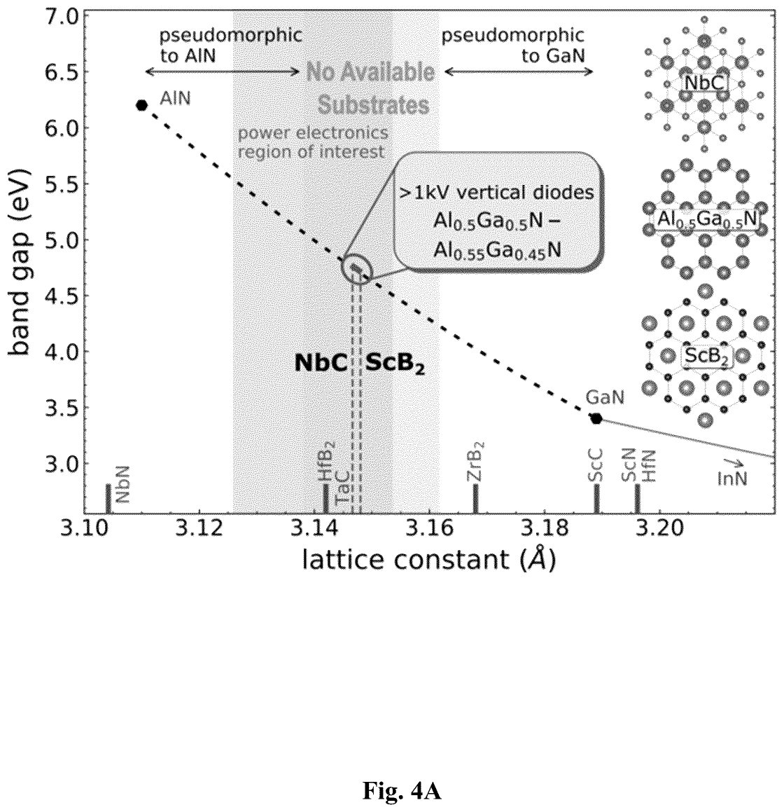

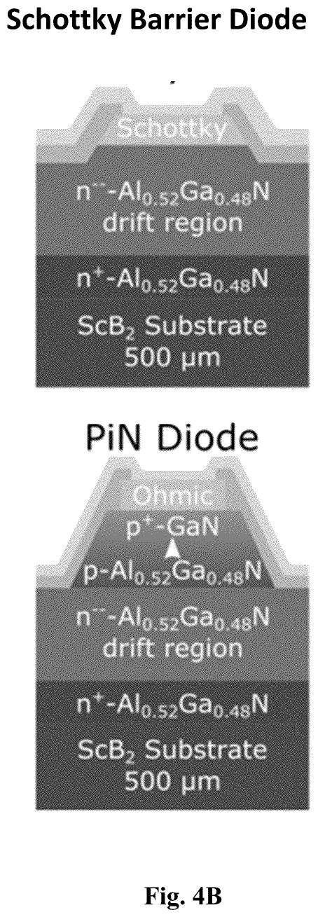

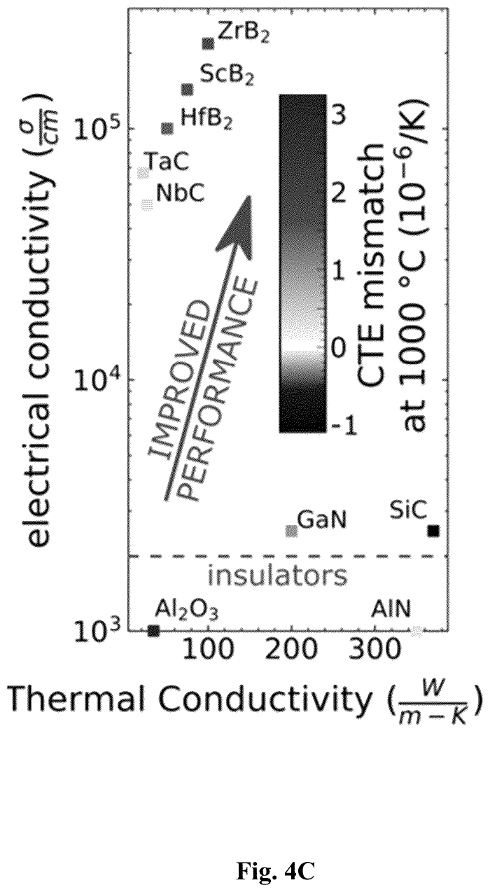

Described herein are metallic ceramic bulk carbide and diboride substrates (ScB2 and NbC), enabling more efficient and lower cost power electronic devices based on ultra-wide bandgap (UWBG) AlGaN alloys that are technologically ideal but currently inaccessible (FIGS. 4A-4C). This research investment will dramatically advance performance of high-current power electronics (>1 kV diodes with 5-10× greater current capacity) while demonstrating scalability and identifying cost savings through coupled experiment and technoeconomic analysis (TEA). The impact would be three-fold: cost-efficient scalable substrates, higher efficiency (lower substrate resistivity), and improved thermal management (higher substrate thermal conductivity). The proposed advances have the potential to disruptively impact ˜80% of the electrical energy power flow.^{1,2} These ambitious research goals will be achieved by combining prototype float-zone (FZ) crystal growth, advanced thin-film growth, and world-class device design and characterization. Our initial demonstration of next-generation AlGaN devices on metallic ceramic FZ substrates could pave the way for future low-cost Czochralski (CZ) substrate growth, offering cost and scale impact for power electronics that Si CZ growth provided for integrated circuits and photovoltaics.

To support rapidly advancing energy transformation, power electronic devices must be able to withstand high temperatures, voltages, and currents, as well as handle higher thermal loads at higher frequencies, well beyond today's state of the art. Currently, 30% of all electrical energy flows through power electronics; this is predicted to increase to 80% in the next 10 years due in large part to increased electric vehicle adoption and renewable energy generation. Next-generation power electronics are critically important to enable large-scale electrification, increased efficiency and decreased greenhouse gas emission everywhere power is generated, distributed, and consumed.

The ideal power electronics material has a wide band gap, high carrier mobility, high thermal conductivity, bipolar dopability, is not metastable, and can be grown by thin film methods on bulk substrates. AlGaN alloys are the only known materials that can check all boxes with the widest band gap but these alloys are currently inaccessible due to substrate limitations. The lack of low cost, high performance substrates is the critical barrier to achieving maximum performance power electronics. Described herein are devices capable of high current, voltage, temperature, and frequency operation, surpassing state-of-the-art figures of merit through innovation in the development and demonstration of novel metallic ceramic substrates for AlGaN materials.

UWBG semiconductors are central to efficient power electronic technologies, deep-ultraviolet (DUV) optoelectronics, high temperature electronics, and GHz+communication. Thus, the next generation of UWBG materials will impact wide sectors of the economy. Extending established GaN devices to higher bandgaps through alloying with AlN (FIGS. 4A-4C) would significantly increase power handling capacity. The low frequency unipolar performance (Baliga figure-of-merit, BFOM) scales as BFOM ˜μ×Eg5.5, therefore a significant increase in the bandgap of the material offers a highly magnified, rather than incremental, increase in performance. Equally important, thermal performance also increases with increasing bandgap. For AlxGa1-xN there are competing effects of increasing alloy scattering (decreased mobility) and increased bandgap for increasing Al fraction, such that improved performance with respect to GaN requires x≥0.3-0.5 depending on temperature. On the other hand, n-type doping becomes difficult in AlxGa1-xN when x>0.85. This leads to a composition “sweet spot” of approximately 50%-80% Al for effective power electronics for which lattice matched substrates are not available (FIGS. 4A-4C). These “sweet spot” AlGaN alloy compositions could deliver disruptive performance if enabled by a parallel substrate breakthrough.

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

AlGaN has not been commercialized due to a lack of lattice-matched substrates. Lattice matching is important for high power devices to reduce dislocations which limit device performance. For high current handling, conductive substrates are required to enable vertical architectures. Additionally, lattice-matched and coefficient of thermal expansion (CTE) matched substrates enable thicker drift layers without cracking, which provide higher voltage blocking. State-of-the-art AlGaN/AlN/Al2O3 total device thicknesses are limited to <5-10 m to avoid CTE-induced cracking. The shaded region in FIG. 4A shows the AlGaN alloy space with no lattice-matched substrate available today regardless of cost or scalability, which significantly overlaps the power electronics region of interest (FIG. 4A). Currently available substrates (and limitations) for the power electronics region of interest are shown in Table 3, along with our proposed solutions ScB2 and NbC. The proposed metallic ceramics are the only known materials that meet all substrate requirements, and similar materials (ZrB2, NbC, TiC, ZrC) have been used successfully for GaN heteroepitaxy.

TABLE 3
Parameters of interest for various potential Al0.5Ga0.5N substrates. No
currently available substrates are lattice-matched (<1%), and are either
insulating or semiconducting, limiting vertical device performance.

| | Melt. | Lattice | | Therm. | | | CTE at |
|---|---|---|---|---|---|---|---|
| | Point | mismatch to | Resistiv. | Cond. | Economic | Physical | 1000° C. |
| Substrate | (° C.) | Al_{0.5}Ga_{0.5}N | (Ω-cm) | (W/m-K) | Scalability | Scalability | (ppm/° C.) |
| Sapphire | 2072 † | 12.7% | Insulating | 35 | Excellent | Excellent | 9.5 |
| SiC | 2730 | 2.2% | ~4 × 10⁻⁴ | 370 | Good | Excellent | 5.15 |
| AlN | 2250 | 1.2% | Insulating | 350 | Poor | Poor | 6.5 |
| GaN* | 2500 | 1.3% | ~2 × 10⁻⁴ | 200 | Very Poor | Very Poor | 6 |
| ScB₂ | 2250 † | ~0% | 7 × 10⁻⁶ | 75 | Present | Excellent* | 7.8* |
| | | | | | Application | | |
| NbC | 3610 † | ~0% | 2 × 10⁻⁵ | 27 | Present | Excellent* | 6.55 |
| | | | | | Application | | |

*Estimated
† Congruently melts—allows single-crystal bulk substrates grown by scalable methods

The described invention may be further understood by the following non-limiting examples:

Example 1. A device comprising:
a semiconducting material comprising AlₓGa₁₋ₓN where 0<x<1;
a substrate having the formula MB₂, wherein B is Boron and M is a metal comprising at least one of the group of Zr, Hf, Sc, Nb, Ta, Ti, V, Cr, Mn, Y, Mo, Mg, Al and U.

Example 2. A device comprising:
a semiconducting material comprising AlₓX₁₋ₓN where 0<x<1; wherein X comprises at least one of the group of Ga, In, Sc, Gd, or a combination thereof; and
a substrate having the formula M₂N or M₂C, wherein C is carbon, N is nitrogen and M is a metal comprising at least one of the group of Zr, Hf, Sc, Nb, Ta, Ti, V, Cr, Mn, Y, Mo, Mg, Al and U.

Example 3. The device of example 1 or 2, wherein the substrate is selected from the group of ScB₂, HfB₂ and ZrB₂.

Example 4. The device any of examples 1-3, wherein the semiconducting material is lattice matched along an in-plane direction (a-direction) to the substrate; wherein the substrate has a lattice mismatch less than or equal to 1% for AlGaN.

Example 5. The device of any of examples 1-4, wherein the AlGaN has an Al mole fraction greater than or equal to 0.5.

Example 6. The device of any of examples 1-5, wherein the substrate has a hexagonal (001) crystal structure.

Example 7. The device of any of examples 1-6, wherein the semiconducting material has an Al mole fraction greater than or equal to 0.4.

Example 8. The device of any of examples 1-7, wherein the substrate exhibits metallic or semimetallic electron transport.

Example 9. The device of example 8, wherein the substrate has a resistance less than or equal to 0.0001 Ωcm.

Example 10. The device of any of examples 1-9, wherein the semiconducting material has a vertical thickness greater than or equal to 1 μm.

Example 11. The device of any of examples 1-10, wherein the device contains an ultra-wide bandgap semiconductor.

Example 12. The device of any of examples 1-11, wherein the device has a vertical or pseudo-vertical orientation.

Example 13. The device of any of examples 1-12, wherein the substrate is removable.

Example 14. The device of example 13, wherein the substrate is a thin film capable of removal via liftoff.

Example 15. The device of example 13, wherein the substrate is a bulk substrate.

Example 16. The device of example 15, wherein the substrate is acid soluble.

Example 17. The device of example 16, wherein the substrate is soluble in HF, HNO₃ or a combination thereof.

Example 18. An epitaxial substrate having the formula MB₂, wherein B is Boron and M is a metal selected from the group of Zr, Hf, Sc, Nb, Ta, Ti, V, Cr, Mn, Y, Mo, Mg, Al and U;
wherein the substrate is lattice matched to AlₓGa₁₋ₓN for 0<x<1; and
wherein the substrate is a single orientation crystal.

Example 19. The substrate of example 18, wherein the substrate is selected from the group of ScB₂, HfB₂ and ZrB₂.

Example 20. The substrate of example 18 or 19, wherein the substrate is removable.

Example 21. The substrate of example 20, wherein the substrate is acid soluble.

Example 22. The substrate of example 21, wherein the substrate is soluble in HF, HNO₃ or a combination thereof.

Example 23. A method comprising:
providing a single orientation crystal epitaxial substrate having the formula MB₂, wherein B is Boron and M is a metal selected from the group of Zr, Hf, Sc, Nb, Ta, Ti, V, Cr, Mn, Y, Mo, Mg, Al and U;
growing a AlₓGa₁₋ₓN semiconductor layer on the substrate;
wherein the substrate is lattice matched to AlₓGa₁₋ₓN.

Example 24. The method of example 23, wherein the AlₓGa₁₋ₓN layer has an Al mole fraction greater than or equal to 0.4.

Example 25. The method of example 23 or 24, wherein the substrate is selected from the group of ScB₂, HfB₂ and ZrB₂.

Example 26. The method of any examples 23-25, further comprising: removing the single orientation crystal epitaxial substrate from the AlₓGa₁₋ₓN semiconductor layer.

Example 27. The method of example 26, wherein the step of removing the single orientation crystal epitaxial substrate is performed by exposing the substrate to an acid.

Example 28. The method of example 27, wherein the acid is HF, HNO₃ or a combination thereof.

Example 29. A method comprising:
providing a epitaxial substrate;
depositing a carbonitride layer comprising a transition metal cation and N, C or a combination thereof on a surface of the high-temperature substrate thereby generating an epitaxial substrate;
growing a AlₓGa₁₋ₓN semiconductor layer on the epitaxial substrate;
removing the epitaxial substrate from the AlₓGa₁₋ₓN semiconductor layer.

Example 30. The method of example 29, wherein the step of removing the epitaxial substrate is performed by exposing the epitaxial substrate to acid.

Example 31. The method of example 30, wherein the acid is HF, HNO₃ or a combination thereof.

Example 32. The method of any of examples 29-31, wherein said high-temperature substrate is a rock salt substrate.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

What is claimed is:

1. A device comprising:
a semiconducting material comprising AlₓGa₁₋ₓN where 0<x<1;
a substrate having the formula MB₂, wherein B is Boron and M is a metal comprising at least one of the group of Zr, Hf, Sc, Nb, Ta, Ti, V, Cr, Mn, Y, Mo, Mg, Al and U.

2. A device comprising:
a semiconducting material comprising AlₓX₁₋ₓN where 0<x<1; wherein X comprises at least one of the group of Ga, In, Sc, Gd, or a combination thereof; and
a substrate having the formula MB₂, wherein B is Boron and M is a metal comprising at least one of the group of Zr, Hf, Sc, Nb, Ta, Ti, V, Cr, Mn, Y, Mo, Mg, Al and U.

3. The device of claim 1, wherein the substrate is selected from the group of ScB₂, HfB₂ and ZrB₂.

4. The device claim 1, wherein the semiconducting material is lattice matched along an in-plane direction (a-direction) to the substrate; wherein the substrate has a lattice mismatch less than or equal to 1% for AlGaN.

5. The device of claim 1, wherein the AlGaN has an Al mole fraction greater than or equal to 0.4.

6. The device of claim 1, wherein the semiconducting material has an Al mole fraction greater than or equal to 0.5.

7. The device of claim 1, wherein the substrate exhibits metallic or semimetallic electron transport and the substrate has a resistance less than or equal to 0.0001 Ωcm.

8. The device of claim 1, wherein the semiconducting material has a vertical thickness greater than or equal to 1 μm.

9. The device of claim 1, wherein the device contains an ultra-wide bandgap semiconductor.

10. The device of claim 1, wherein the device has a vertical or pseudo-vertical orientation.

11. The device of claim 1, wherein the substrate is removable.

12. The device of claim 11, wherein the substrate is a thin film capable of removal via liftoff.

13. The device of claim 11, wherein the substrate is a bulk substrate.

14. The device of claim 13, wherein the substrate is acid soluble.

15. The device of claim 15, wherein the substrate is soluble in HF, HNO₃ or a combination thereof.

16. A method comprising:
providing a single orientation crystal epitaxial substrate having the formula MB₂, wherein B is Boron and M is a metal selected from the group of Zr, Hf, Sc, Nb, Ta, Ti, V, Cr, Mn, Y, Mo, Mg, Al and U;
growing a AlₓGa₁₋ₓN semiconductor layer on the substrate;
wherein the substrate is lattice matched to AlₓGa₁₋ₓN.

17. The method of claim 16, wherein the AlₓGa₁₋ₓN layer has an Al mole fraction greater than or equal to 0.4.

18. The method of claim 16, wherein the substrate is selected from the group of ScB₂, HfB₂ and ZrB₂.

19. The method of claim 16, further comprising:
removing the single orientation crystal epitaxial substrate from the AlₓGa₁₋ₓN semiconductor layer.

20. The method of claim 19, wherein the step of removing the single orientation crystal epitaxial substrate is performed by exposing the substrate to an acid.
